(19) United States
(12) Patent Application Publication
(10) Pub. No.: US 2026/0179206 A1
(43) Pub. Date: Jun. 25, 2026

(54) TRANSFER ROBOT AND SUBSTRATE PROCESSING APPARATUS

(71) Applicant: SEMES CO., LTD., Cheonan-si (KR)

(72) Inventors: Sang Mo YANG, Seoul (KR); Jun Yeop LEE, Yongin-si (KR); Ji Young LEE, Suwon-si (KR); Young Ho PARK, Incheon (KR)

(73) Assignee: SEMES CO., LTD., Cheonan-si (KR)

(21) Appl. No.: 19/420,874

(22) Filed: Dec. 16, 2025

(30) Foreign Application Priority Data
Dec. 24, 2024 (KR) 10-2024-0195178

(51) Int. Cl. G06T 7/00; B25J 11/00; B25J 15/00; B25J 19/02; G06T 7/70; H10P 72/00; H10P 72/76

(52) U.S. Cl. CPC G06T 7/0004; B25J 11/0095; B25J 15/0014; B25J 15/0052; B25J 19/023; G06T 7/70; H10P 72/0606; H10P 72/7602; G06T 2207/20212; G06T 2207/30148

(57) ABSTRACT

Provided is a transfer robot for transferring a substrate. The transfer robot includes: a base; a plurality of arms installed above the base to be vertically spaced apart and to extend and retract in a forward and backward direction relative to the base, each having a hand supporting the substrate; and a photographing unit disposed above the base and photographing an area of each of the plurality of hands in which the substrate is placed, and an area photographed by the photographing unit includes an edge area of the substrate.

### CROSS-REFERENCE TO RELATED APPLICATION

This application claims priority to and the benefit of Korean Patent Application No. 10-2024-0195178 filed in the Korean Intellectual Property Office on Dec. 24, 2024, the entire contents of which are incorporated herein by reference.

### TECHNICAL FIELD

The present invention relates to a transfer robot and a substrate processing apparatus, and more specifically, to a transfer robot that transfers a substrate and a substrate processing apparatus including the same.

### BACKGROUND ART

To manufacture a semiconductor device or liquid crystal display, various processes, such as photolithography, etching, ashing, ion implantation, and thin film deposition, are performed on a substrate. These processes use a technology of checking whether a hand of a transfer robot holds and supports a substrate and whether the substrate is seated on the hand when the substrate is transferred using the transfer robot. For example, optical sensors are used to detect whether the substrate is seated on the hand and whether the substrate is separated. When a transfer robot has a plurality of hands, an optical sensor in the related art in which a light emitting unit and a light receiving unit are installed in the vertical direction may detect whether a substrate is separated, but has a problem in that it is impossible to determine which of the plurality of hands the substrate is separated from, and it is impossible to calculate an error in the height direction of the substrate, and multiple sensors are required to determine whether the substrate is seated on each hand.

### SUMMARY OF THE INVENTION

The present invention has been made in an effort to provide a transfer robot capable of checking whether a substrate is seated and whether the substrate is separated for each of a plurality of hands, and a substrate processing apparatus including the same.

The present invention has been made in an effort to provide a transfer robot that simplifies the configuration of detecting whether a substrate is seated and whether a substrate is separated, and a substrate processing device including the same.

The present invention has been made in an effort to provide a transfer robot capable of calculating an alignment error of a substrate by calculating a position of a substrate seated on a hand, and a substrate processing device including the same.

The objectives of the present disclosure are not limited thereto and other objectives not stated herein may be clearly understood by those skilled in the art from the following description.

An exemplary embodiment of the present disclosure, a transfer robot for transferring a substrate, the transfer robot comprising: a base; a plurality of arms installed above the base to be vertically spaced apart and to extend and retract in a forward and backward direction relative to the base, each having a hand supporting the substrate; and a photographing unit disposed above the base and photographing an area of each of the plurality of hands in which the substrate is placed, and an area photographed by the photographing unit may include an edge area of the substrate.

According to the exemplary embodiment of the present invention, wherein the photographing units are provided in a pair, and the pair of photographing units may be arranged to photograph different areas of the substrate placed on the hand, respectively.

According to the exemplary embodiment of the present invention, wherein the edge areas of the substrate photographed by the pair of photographing units may be configured to be symmetrical based on a center line passing through a center of the substrate placed on the hand and parallel to the forward and backward direction of the hand when viewed from above.

According to the exemplary embodiment of the present invention, wherein the optical paths of the pair of photographing units may be configured to be perpendicular to each other when viewed from above.

According to the exemplary embodiment of the present invention, wherein the photographing unit may include: a camera; and a mirror for changing an optical path of the camera.

According to the exemplary embodiment of the present invention, wherein the photographing unit further may include a polarization filter.

According to the exemplary embodiment of the present invention, wherein the photographing unit may be fixedly installed on the base.

According to the exemplary embodiment of the present invention, further comprising: a controller, the photographing unit acquires an image by photographing an area of each of the plurality of hands in which the substrate is placed, and the controller may determines whether the substrate is seated on each of the plurality of hands and whether the substrate is seated in a correct position from the image acquired by the photographing unit.

According to the exemplary embodiment of the present invention, wherein the controller combines the images acquired by each of the pair of photographing units to acquire coordinates of the substrate placed on each of the plurality of hands, and may determines whether the substrate is seated in the correct position by using the acquired coordinates of the substrate.

According to the exemplary embodiment of the present invention, wherein the controller extracts image data in which a focusing area is set to be limited to an edge area of the substrate from the image acquired by the photographing unit and may determines whether the substrate is seated and whether the substrate is seated in the correct position.

According to the exemplary embodiment of the present invention, wherein at least one of the plurality of arms includes a plurality of hands, and the plurality of hands may be provided to be coupled to the one arm so as to be spaced apart from each other in a vertical direction.

An exemplary embodiment of the present disclosure, an apparatus for processing a substrate, the apparatus comprising: an index module including a load port for loading and unloading a substrate; a processing module including a process chamber for processing a substrate; a controller; and a transfer robot for transferring the substrate between the index module and the processing module, wherein the transfer robot includes: a base; a plurality of arms installed above the base to be vertically spaced apart and to extend and retract in a forward and backward direction relative to the base, each having a hand supporting the substrate; and a pair of photographing units disposed above the base, each of the plurality of arms includes one or more hands, the photographing units photographs an area of each of a plurality of hands in which a substrate is placed at a time, and the area that the photographing unit photographs may include an edge area of the substrate placed on the hand.

According to the exemplary embodiment of the present invention, wherein the edge areas of the substrate photographed by the pair of photographing units may be configured to be symmetrical based on a center line passing through a center of the substrate placed on the hand and parallel to the forward and backward direction of the hand when viewed from above.

According to the exemplary embodiment of the present invention, wherein optical paths of the pair of photographing units may be configured to be perpendicular to each other when viewed from above.

According to the exemplary embodiment of the present invention, wherein the photographing unit may include: a camera; a mirror for changing the optical path of the camera; and a polarization filter.

According to the exemplary embodiment of the present invention, wherein the photographing unit may be fixedly installed on the base.

According to the exemplary embodiment of the present invention, further comprising: a controller, wherein the photographing unit acquires an image by photographing an area of each of the plurality of hands in which the substrate is placed, and the controller may determines whether the substrate is seated on each of the plurality of hands and whether the substrate is seated in a correct position from the image acquired by the photographing unit.

An exemplary embodiment of the present disclosure, a transfer robot for transferring a substrate, the transfer robot comprising: a base; a plurality of arms installed above the base to be vertically spaced apart and to extend and retract in a forward and backward direction relative to the base, each having a hand supporting the substrate; and a pair of photographing units fixedly installed on the base and photographing an area of each of the plurality of hands in which the substrate is placed, and the pair of photographing units is arranged to photograph different areas of the substrate placed on the hand, respectively, each photographing unit includes: a camera; a mirror for changing an optical path of the camera; and a polarization filter, optical paths of the pair of photographing units are configured to be perpendicular to each other when viewed from above, the pair of photographing units is arranged to photograph different areas of the substrate placed on the hand, respectively, and an area photographed by the photographing unit may includes an edge area of the substrate.

According to the exemplary embodiment of the present invention, further comprising: a controller, wherein the photographing unit acquires an image by photographing an area of each of the plurality of hands in which the substrate is placed, and the controller may determines whether the substrate is seated on each of the plurality of hands and whether the substrate is seated in a correct position from the image acquired by the photographing unit.

According to the exemplary embodiment of the present invention, wherein the controller extracts image data in which a focusing area is set to be limited to an edge area of the substrate from the image acquired by the photographing unit and may determines whether the substrate is seated and whether the substrate is seated in the correct position.

According to the exemplary embodiment of the present invention, it is possible to check whether a substrate is seated and whether the substrate is separated for each of the plurality of hands.

Further, according to the exemplary embodiment of the present invention, it is possible to simplify the configuration of the transfer robot of detecting whether a substrate is seated and whether a substrate is separated.

Further, according to the exemplary embodiment of the present invention, it is possible to calculate an alignment error of a substrate by calculating a position of a substrate seated on a hand.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a perspective view illustrating a first transfer robot according to an exemplary embodiment of the present invention.

FIG. 3 is a plan view illustrating a photographing unit and an optical path according to the photographing unit according to an exemplary embodiment of the present invention.

FIG. 4 is a side view schematically illustrating a state in which the photographing unit of FIG. 2 photographs a substrate.

FIG. 5 is a diagram illustrating a correlation between an optical path of the photographing unit of FIG. 2 and a position of a substrate.

FIG. 6 is a diagram illustrating an area in which the photographing unit of FIG. 2 photographs a substrate.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on a process of liquid-treating a substrate W by supplying a liquid, such as a cleaning liquid, onto a substrate W as an example. However, the present exemplary embodiment is not limited to the cleaning process, and may be applied to various processes of processing the substrate W using a liquid, such as an etching process, an ashing process, or a developing process.

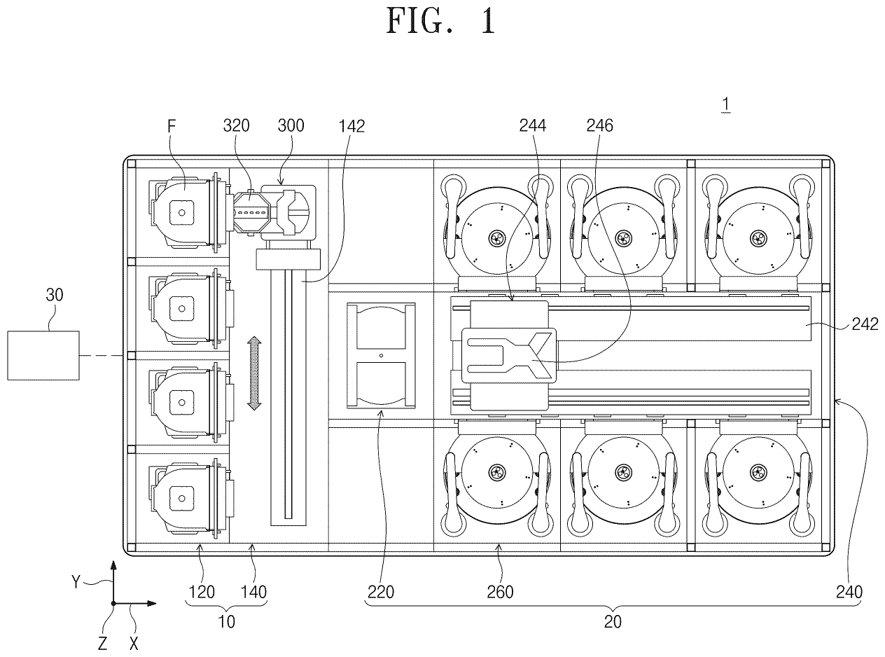

Hereinafter, an exemplary embodiment of the present invention will be described in detail with reference to FIGS. 1 to 6. A substrate processing apparatus 1 according to an exemplary embodiment of the present invention may perform a cleaning process including a drying process of drying a substrate W using a process fluid.

FIG. 1 is a diagram schematically illustrating a substrate processing apparatus according to an exemplary embodiment of the present invention. Referring to FIG. 1, a substrate processing apparatus 1 includes an index module 10, a processing module 20, and a controller 30. According to an example, the index module 10 and the processing module 20 are disposed along one direction. Hereinafter, a direction in which the index module 10 and the processing module 20 are arranged is defined as a first direction X. When viewed from above, a direction perpendicular to the first direction X is defined as a second direction Y, and a direction perpendicular to a plane including both the first direction X and the second direction Y is defined as a third direction Z.

The index module 10 transfers a substrate W from a container F in which the substrate W is accommodated to the processing module 20 processing the substrate W. The index module 10 accommodates the substrate W completely processed in the processing module 20 in the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the processing module 20. A plurality of load ports 120 may be provided. The plurality of load ports 120 may be arranged in a line along the second direction Y. The number of load ports 120 may increase or decrease according to the process efficiency and footprint conditions of the processing module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and a first transfer robot 300 are provided inside the index frame 140. The index rail 142 is provided in the index frame 140 along the second direction Y in its longitudinal direction. The first transfer robot 300 may transfer the substrate W.

The first transfer robot 300 may transfer the substrate W between the index module 10 and the processing module 20. The first transfer robot 300 may transfer the substrate W between the load port 120 and a buffer chamber 220 to be described below. The first transfer robot 300 may be called as an index robot. A detailed configuration of the first transfer robot 300 will be described later.

The first transfer robot 300 includes a plurality of hands 320. The substrate W is seated on the hand 320. The first transfer robot 300 may be provided to be movable on the index rail 142 along the second direction Y. Accordingly, the hand 320 may forward and backward along the index rail 142. Also, the first transfer robot 300 may be provided to be rotatable with respect to the third direction Z as an axis. Also, the first transfer robot 300 may be provided to be movable vertically along the third direction Z. The first transfer robot 300 will be described later.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform a substrate processing method described below. For example, the controller 30 may control the configurations provided to the first transfer robot 300, a second transfer robot 244, and a process chamber 260 to be described below to perform a substrate processing method described below.

The processing module 20 includes a buffer chamber 220, a transfer frame 240, and a process chamber 260. The buffer chamber 220 provides a space in which the substrate W loaded into the processing module 20 and the substrate W unloaded from the processing module 20 stay temporarily. The transfer frame 240 provides a transfer space for transferring the substrate W between the buffer chamber 220 and the process chamber 260.

The buffer chamber 220 may be disposed between the index frame 140 and the transfer chamber 240. The buffer chamber 220 may be located at one end of the transfer frame 240. A slot (not illustrated) in which the substrate W is placed is provided in the buffer chamber 220. A plurality of slots (not illustrated) is provided. A plurality of slots (not illustrated) may be disposed to be spaced apart from each other along the third direction Z. A front face and a rear face of the buffer chamber 220 are opened. The front face is a face facing the index module 10, and the rear face is a face facing the transfer frame 240. The first transfer robot 1 may approach the buffer chamber 220 through the front face, and the second transfer robot 244 may approach the buffer chamber 220 through the rear face.

A longitudinal direction of the transfer frame 240 may be provided along the first direction X. The process chambers 260 may be disposed on opposite sides of the transfer frame 240. The process chamber 260 may be disposed on a side portion of the transfer frame 240. The transfer frame 240 and the process chamber 260 may be disposed along the second direction Y.

According to the example, the process chambers 260 are disposed on opposite sides of the transfer frame 240. At one side of the transfer frame 240, the process chambers 260 may be provided in an array of A×B (each of A and B is 1 or a natural number larger than 1) in the first direction X and the third direction Z. Herein, A is the number of process chambers 260 provided in a row along the first direction X, and B is the number of process chambers 260 provided in a row along the third direction Z. For example, when six process chambers 260 are provided at one side of the transfer frame 240, the process chambers 260 may be arranged in a 3×2 array. The number of process chambers 260 may increase or decrease. Unlike the above description, the process chambers 260 may be provided as a single layer on one side and opposite sides of the transfer frame 240.

The transfer frame 240 includes a guide rail 242 and a second transfer robot 244. The guide rail 242 is provided within the transfer frame 240 in the first direction X in a longitudinal direction thereof. The second transfer robot 244 may be provided on the guide rail to be able to move linearly in the first direction X. The second transfer robot 244 transfers the substrate W between the buffer chamber 220 and the process chamber 260.

The process chamber 260 may process the substrate W. The process chamber 260 may be a chamber for performing a cleaning process for removing process by-products or the like attached to the substrate W. The process chamber 260 may be provided as, for example, a liquid treating chamber 400 to perform a liquid treatment process of liquid-treating the substrate W by supplying a liquid onto the substrate W. Hereinafter, the present invention will be described based on the case where the process chamber 260 is the liquid treating chamber 400 as an example. The liquid treating chamber 400 may process the substrate W by supplying a chemical, a rinse liquid, and/or an organic solvent onto the substrate W. The processing of the substrate W performed in the liquid treating chamber 400 may include a spin drying treatment in which the liquid remaining on the substrate W is removed by rotating the substrate W.

The process chamber 260 may have different structures depending on the type of process for processing the substrate W. Alternatively, each of the process chambers 260 may have the same structure.

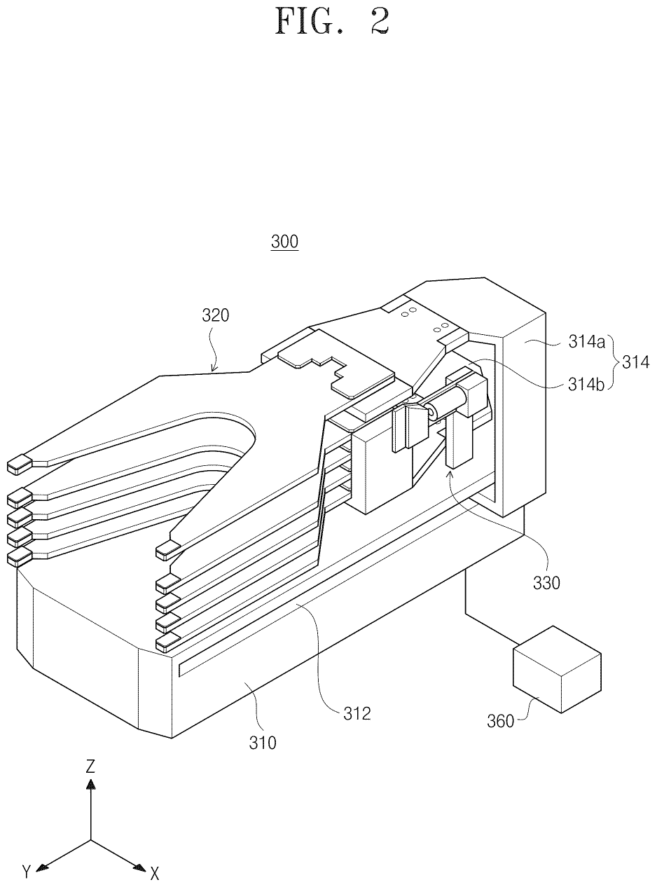

FIG. 2 is a perspective view illustrating the first transfer robot according to a first exemplary embodiment of the present invention. Referring to FIGS. 1 and 2, the first transfer robot 300 includes a base 310, an arm 314, a hand 320, a photographing unit 330, and a driving unit 360.

The base 310 supports the arm 314 and the hand 320 connected to the arm 314. The arm 314 is connected with the base 310. An end of the arm 314 is connected to the hand 320.

The base 310 is installed to be movable along the index rail 142. The base 310 may be axially rotated with respect to a support shaft (not illustrated) in the third direction Z. The base 310 may have a generally rectangular parallelepiped shape. The base 310 is provided such that a longitudinal direction thereof is directed in a horizontal direction. A guide 312 is provided on the base 310. The guide 312 guides the moving direction of the arm 314 so that the arm 314 and the hand 320 coupled to the arm 314 may move linearly along the longitudinal direction of the base 310. A plurality of guides 312 may be provided. The arm 314 is provided to be able to forward and backward with respect to the base 310 by the driving unit 380. When the arm 314 extends with respect to the base 310, the hand 320 may be placed in an extended position, and when the arm 314 retracts with respect to the base 310, the hand 320 may be placed in a retracted position. When the hand 320 is placed in the retracted position, the hand 320 may be located above the base 310.

According to an example, the same number of guides 312 as the number of arms 314 may be provided. Each of the guides 312 may be provided such that a longitudinal direction thereof is parallel to the base 310.

The arm 314 and the hand 320 coupled to the arm 314 may be stacked above the base 310 to be spaced apart from each other in the vertical direction Z and may be provided in plural. A plurality of arms 314 may linearly move independently of each other by the driving unit 360.

In the following exemplary embodiment, it will be illustrated and described that the first transfer robot 300 includes two arms 314 and five hands 320, including the arm 314 coupled with one hand 320 and the arm 314 coupled with four hands 320, but unlike this, the numbers of arms 314 and hands 320 may be freely changed according to the process efficiency of the substrate processing apparatus 1.

The hand 320 supports the substrate W. The hand 320 is coupled to the arm 314. The substrate W is seated on the hand 320. The hand 320 may include a guide (not illustrated) supporting a lower surface area of an edge of the substrate W when the substrate W is seated thereon. The guide (not illustrated) may further perform a function of restricting lateral movement of the substrate W by guiding the side surface of the substrate W when the substrate W is placed on a support surface.

The photographing unit 330 may photograph an area in which the substrate W is placed for the plurality of hands 320. The photographing unit 330 may acquire image data by photographing an area of each of the plurality of hands 320 in which the substrate W is placed.

The photographing unit 330 may be arranged to photograph an area of each of the plurality of hands 320 in which the substrates W are placed when the hands 320 are in the retreat position. The photographing unit 330 may be disposed above the base 310. The photographing unit 330 may be fixedly installed on the base 310. A plurality of photographing units 330 may be provided. For example, the photographing units 330 may be provided in a pair and installed on opposite sides of the hand 320 on the base 310, respectively. The pair of photographing units 330 may be arranged to photograph different areas of the substrate W placed on the hand 320. In the following exemplary embodiment, it will be illustrated and described that the photographing units 330 are provided in a pair and installed on opposite sides of the hand 320, respectively, when viewed from above.

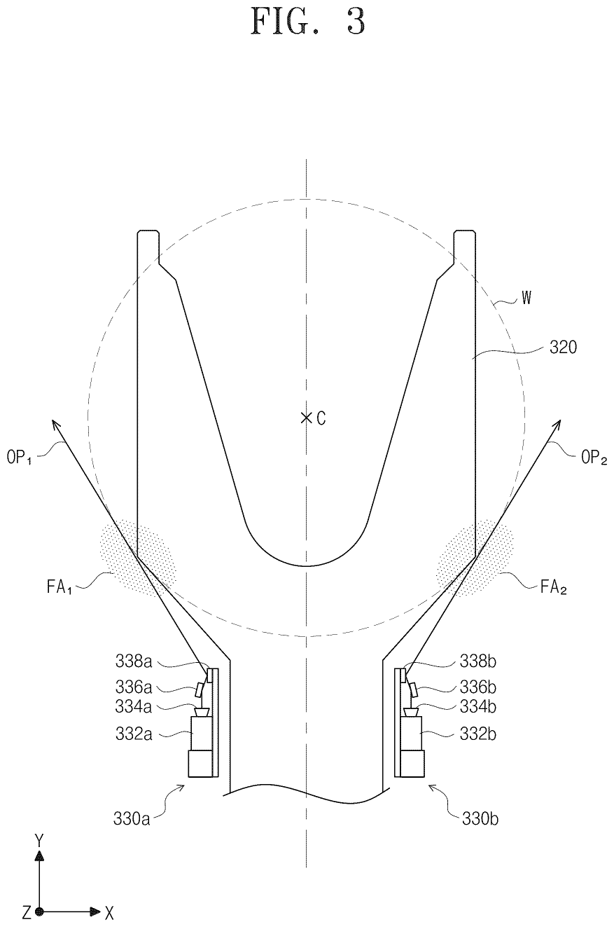

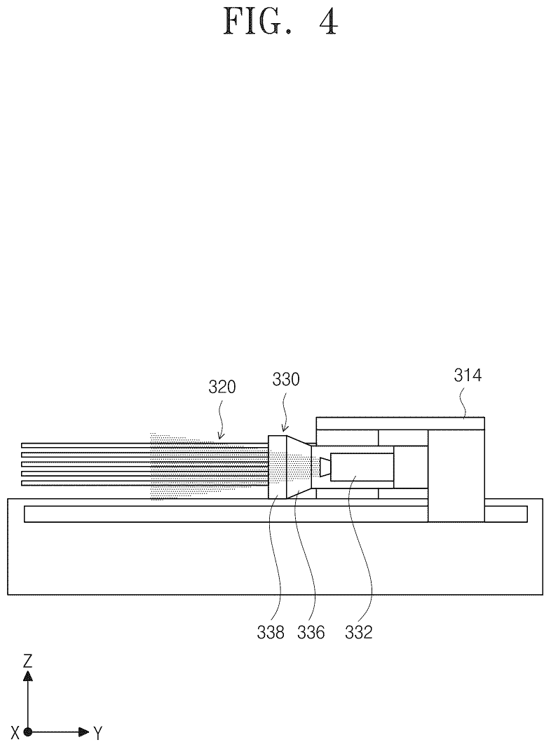

FIG. 3 is a plan view illustrating the photographing unit and an optical path according to the photographing unit according to the exemplary embodiment of the present invention, and FIG. 4 is a side view schematically illustrating a state in which the photographing unit of FIG. 2 photographs a substrate. Referring further to FIGS. 2 to 4, the photographing unit 330 may be provided on opposite sides of the hand 320. For convenience of description, the photographing unit 330 illustrated on the left side of the hand 320 in the plan view of FIG. 3 will be referred to as a first photographing unit 330a, and the photographing unit 330 illustrated on the right side of the hand 320 will be referred to as a second photographing unit 330b.

Each photographing unit 330 may include a camera 332, a polarization filter 334, and mirrors 336 and 338. For example, the first photographing unit 330a includes a camera 332a, a polarization filter 334a, and mirrors 336a and 338a, and the second photographing unit 330b includes a camera 332b, a polarization filter 334b, and mirrors 336b and 338b.

The camera 332 is a photographing device including an optical system, such as a lens, and an image sensor, and may acquire image data by photographing an area of the hand 320 where the substrate W is placed. The camera 332 may be disposed to form an Optical Path (OP) toward an edge area of the substrate W, as described later, and may photograph an image including the edge area of the substrate W.

The camera 332 may further include a processor. The camera 332 may process image data acquired through the processor and then transmit the processed image data to the controller 30. The processor may be composed of one or more processors or microprocessors. For example, the processor may include a controller for controlling the camera 332, a video codec for processing an image signal provided from the camera 332, and a cache memory.

The polarization filter 334 may be attached to the lens of the camera 332 in a film form. Alternatively, the polarization filter 334 may be disposed on an optical path of the camera 332. The polarization filter 334 may allow a specific polarization component in an image acquired by the camera 332 to pass. When the camera 332 photographs the substrate W, the polarization filter 334 may block reflected light reflected from the substrate W.

The mirrors 336 and 338 may change the optical path OP of the camera 332. The mirrors 336 and 338 may be disposed on the optical path OP of the camera 332 to change the optical path OP of the camera 332 so as to photograph an image including the edge area of the substrate W by the camera 332.

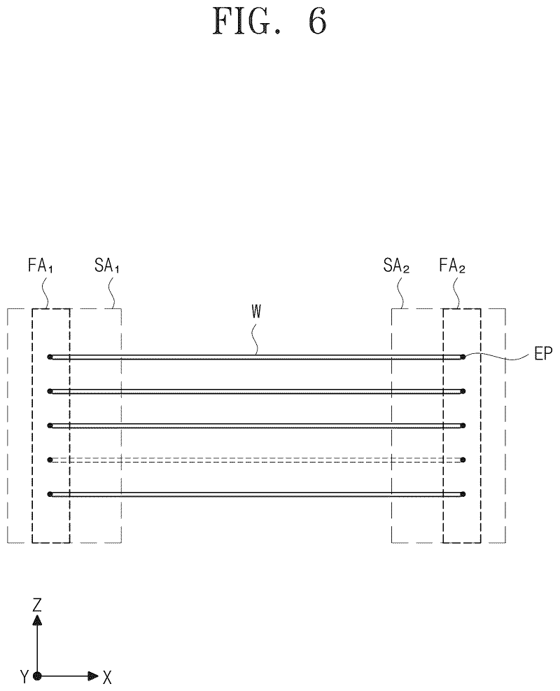

An optical path OP₁ of the first photographing unit 330a and an optical path OP₂ of the second photographing unit 330b are illustrated in FIG. 3. Each optical path OP may be defined as a specific path which is in contact with the edge of the substrate W among paths of light emitted from the cameras 332a and 332b when viewed from above. As illustrated in FIG. 3, each of the optical path OP₁ of the first photographing unit 330a and the optical path OP₂ of the second photographing unit 330a are in contact with the edge area of the substrate W placed on the hand 320. In other words, each of the first photographing unit 330a and the second photographing unit 330a may photograph a different edge area of the substrate W. Referring to FIG. 6, points at which the optical paths OP of the photographing units 330 are in contact with the substrate W may be defined as edge points EPs.

Each of the edge areas of the substrate W photographed by the first photographing unit 330a and the second photographing unit 330a may be configured to be symmetrical with respect to a center line that passes through a center C of the substrate W placed on the hand 320 and is parallel to the second direction Y, which is the forward and backward direction of the hand 320, when viewed from above.

The photographing unit 330 may extract image data limited to a focusing area FA from the photographed image data and transmit the extracted image data to the controller 30. The focusing area FA may include the edge area of the substrate W. The focusing area FA will be described later.

FIG. 4 illustrates a state in which the photographing unit of FIG. 2 photographs a substrate. The photographing unit 330 may photograph the plurality of hands 320 of the transfer robot 300 at a time. In other words, the photographing unit 330 may photograph the plurality of hands 320 at a time to acquire image data including the edge area of the substrate W placed on each of the hands 320.

The controller 30 may determine whether the substrate W is seated on the hand 320 and whether the substrate W is separated from a seating position, from the image data acquired by the photographing unit 330.

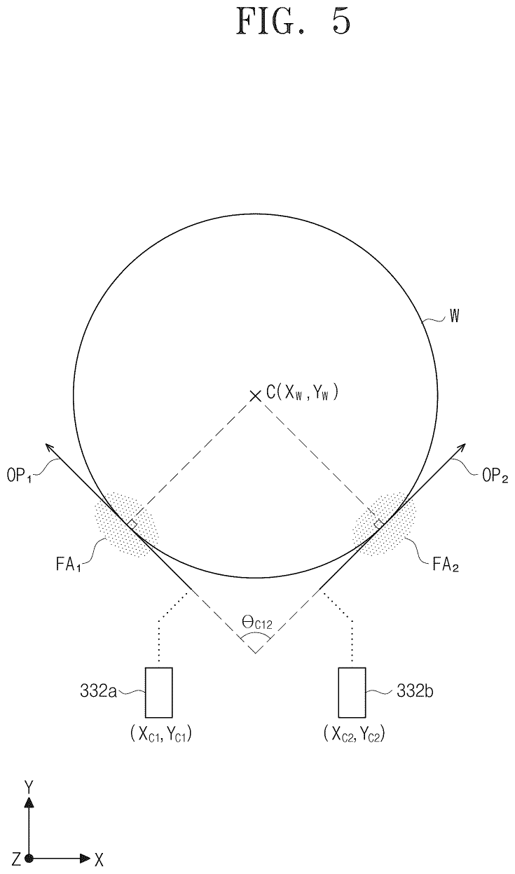

FIG. 5 is a diagram illustrating a correlation between the optical path of the photographing unit of FIG. 2 and a position of a substrate, and FIG. 6 is a diagram illustrating an area in which the photographing unit of FIG. 2 photographs a substrate. Hereinafter, a detailed method of determining, by the transfer robot, whether the substrate is seated and whether the substrate is separated in the substrate processing apparatus according to the exemplary embodiment of the present invention will be described with reference to FIGS. 2 to 6.

As described above, the pair of photographing units 330a and 330b may acquire images by photographing different edge areas of the substrates W placed on the plurality of hands 320 through the cameras 332a and 332b, respectively.

In FIG. 6, an area of the image acquired by the camera 332a of the first photographing unit 330a is illustrated as a first area SA₁, and an area of the image acquired by the camera 332b of the second photographing unit 330a is illustrated as a second area SA₂. FIG. 6 shows the shape of the substrates W placed on each hand 320 instead of omitting the hand 320. The substrate W illustrated by a solid line shows a case where the substrate W is seated on the hand 320, and the substrate W illustrated by a dotted line shows a case where the substrate W is not placed on the hand 320.

In order to determine whether the substrate W is seated on each of the plurality of hands 320, it is necessary to check whether edge points EP corresponding to both ends of the substrate W placed on each hand 320 in the first direction X are specified in the area which each of the photographing units 330 in the pair photographs. As illustrated in FIG. 6, the photographing units 330 may photograph different edge areas of the substrate W, respectively, and extract image data.

In this case, since the area including the edge point EP of the substrate W is a main area of interest, that is, the focusing area FA that is the target of focusing, the photographing unit may extract image data in which the focusing area FA is set so as to be limited to the edge area of the substrate W from the entire area of the image acquired by the photographing unit 330 to increase a processing speed of the image data.. The setting of the focusing area FA may be performed by a method of cropping the remaining areas except for the focusing area FA in the transmitted image data.

Specifically, as illustrated in FIG. 6, a first focusing area FA₁ limited to the edge area of the substrate W may be set so as to acquire the edge point EP of the substrate W in the first area SA₁, which is the entire area of the image acquired by the camera 332a of the first photographing unit 330a, and a second focusing area FA₂ limited to the edge area of the substrate W may be set so that the second photographing unit 330b also acquires the edge point EP of the substrate W in the second area SA₂.

The photographing unit 330 may transmit the extracted image data to the controller 30. In this case, the processor (not illustrated) included in the camera 332 may process the acquired image data and then transmit the processed image data to the controller 30.

The controller 30 may determine whether the substrate W is seated on each of the hands 320 from the image acquired by the photographing unit 330. When it is determined that the substrate W does not exist in the focusing areas FA₁ and FA₂ by analyzing the acquired image, the controller 30 may determine that the substrate W is not seated on the hand 320. For example, the substrate W illustrated in a dotted line in FIG. 6 represents a case where the substrate W is not placed on the hand 320, and the controller 30 may analyze the image data including the focusing areas FA₁ and FA₂ and determine that the substrate W is not seated on the hand 320.

Furthermore, the controller 30 may determine whether the substrate W is aligned in each of the plurality of hands 320 from the image acquired by the photographing unit 330. To determine whether the substrate W is aligned in each of the plurality of hands 320, it is necessary to acquire the coordinates of the substrates W placed on each of the plurality of hands 320. The controller 30 may combine the image data received from each of the pair of photographing units 330 to determine whether the substrate W is seated in the correct position with respect to the center coordinates (X_{W}, Y_{W}) of the substrate W placed on each of the plurality of hands 320.

A linear component of the optical path OP₁ of the first photographing unit 330a illustrated in FIG. 5 may be mathematically defined from the arrangement of the coordinates (X_{C1}, Y_{C1}) in which the camera 332a of the first photographing unit 330a is installed, the camera 332a, and the mirrors 336a and 338a.

In addition, the linear component of the optical path OP₂ of the second photographing unit 330b illustrated in FIG. 5 may be mathematically defined from the arrangement of the coordinates (X_{C2}, Y_{C2}) of the camera 332b of the second photographing unit 330b, the camera 332b, and the mirrors 336b and 338b.

Since the diameter of the substrate W is known, the coordinates (X_{W}, Y_{W}) of the center point of the substrate W may be derived using the two optical paths OP₁ and OP₂, and it may be determined whether the substrate W is deviated in the first direction X and the second direction Y. In addition, an error with respect to the correct position in the first direction X and the second direction Y may be determined.

When the substrate W is inclined without being seated in the correct position, since the coordinates of the edge point EP of the substrate W in the third direction Z derived from the image data are different from the coordinates of the edge point EP of the substrate W placed in the correct position in the third direction Z, the controller 30 may determine whether the substrate W is separated in the third direction Z, and may also calculate an error with the correct position in the third direction Z.

As illustrated in FIG. 5, the optical paths OP₁ and OP₂ of a pair of photographing units 330 form a predetermined angle θ_{C12}. When the optical paths OP₁ and OP₂ are configured to be parallel to each other, it may be difficult to calculate an error in the second direction Y of the substrate W. To calculate an alignment error of the substrate W using the optical paths OP₁ and OP₂ or to specify the edge point EP placed on the substrate W from image data, the photographing units 330 may be arranged so that the pair of optical paths OP₁ and OP₂ are perpendicular to each other based on the substrate W seated in the correct position when viewed from above. However, it is sufficient if the photographing unit 330 is arranged to specify the edge points EP of the substrates W placed on the plurality of hands 320 using the above-described method, and to determine whether the substrate W is seated on the hand 320 and whether the substrate W is seated in the correct position.

According to the above-described exemplary embodiment, the transfer robot 300 includes the photographing unit 330, and the photographing unit 330 acquires image data by photographing the plurality of hands 320 stacked to be spaced apart in the third direction Z, thereby determining whether the substrate W is seated on each of the plurality of hands 320 and whether the substrate W is seated in the correct position.

In addition, as a pair of photographing units 330 photographs different edge areas of the substrate W, the center coordinates (X_{W}, Y_{W}) of the substrate W may be calculated and derived by combining image data, and the alignment error in the first direction X, the second direction Y, and the third direction Z of the substrate W may be calculated.

Accordingly, since it is possible to determine the presence or absence of the substrate W on the plurality of hands 320 and whether the substrate W is seated in the correct position without attaching a separate sensor to each of the plurality of hands 320, the transfer robot 300 of the present invention may simplify the configuration of detecting whether the substrate W is seated on the plurality of hands 320 and whether the substrate is separated.

In the above-described exemplary embodiment, although the photographing unit 330 is illustrated and described as including two mirrors 336 and 338, the number of mirrors included in the photographing unit 330 and the arrangement relationship thereof may be freely changed depending on the arrangement position of the camera 332 and the position of the focus area FA. In addition, the photographing unit 330 may be arranged to directly photograph different edge areas of the substrate W without including a mirror.

In the above-described exemplary embodiment, it has been illustrated and described that a pair of photographing units 330 is fixedly installed on the base 310. However, it is sufficient if the pair of photographing units 330 is arranged to photograph different areas of the substrate W placed on each hand 320. For example, the pair of photographing units 330 may be provided in combination with the arm 314.

In the above-described exemplary embodiment, it has been illustrated and described that the photographing units 330 are provided in a pair. However, it is sufficient if the photographing unit 330 is arranged to photograph edge areas of the substrate W located in different areas with respect to the center C of the substrate W along the first direction X. For example, one photographing unit 330 may be provided and arranged to specify edge points EP corresponding to both ends of the substrate W in the first direction X.

In the above exemplary embodiment, only the first transfer robot 300 is described, and a description of the second transfer robot 244 is omitted. However, the configuration of the above-described first transfer robot 300 may be equally applied to the second transfer robot 244. For example, the second transfer robot 244 may include a plurality of arms 314 to which one hand 320 is coupled. Each arm 314 may be driven simultaneously or independently, and whether the substrate W is seated on or separated from the plurality of hands 320 may be determined using the photographing unit 330.

In the above-described exemplary embodiment, it is exemplified that the photographing unit 330 includes the camera 332, but unlike this, the photographing unit 330 may be transformed to include various configurations including an image sensor.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A transfer robot for transferring a substrate, the transfer robot comprising:
a base;
a plurality of arms installed above the base to be vertically spaced apart and to extend and retract in a forward and backward direction relative to the base, each having a hand supporting the substrate; and
a photographing unit disposed above the base and photographing an area of each of the plurality of hands in which the substrate is placed, and
an area photographed by the photographing unit includes an edge area of the substrate.

2. The transfer robot of claim 1, wherein the photographing units are provided in a pair, and
the pair of photographing units is arranged to photograph different areas of the substrate placed on the hand, respectively.

3. The transfer robot of claim 2, wherein the edge areas of the substrate photographed by the pair of photographing units are configured to be symmetrical based on a center line passing through a center of the substrate placed on the hand and parallel to the forward and backward direction of the hand when viewed from above.

4. The transfer robot of claim 2, wherein the optical paths of the pair of photographing units are configured to be perpendicular to each other when viewed from above.

5. The transfer robot of claim 2, wherein the photographing unit includes:
a camera; and
a mirror for changing an optical path of the camera.

6. The transfer robot of claim 5, wherein the photographing unit further includes a polarization filter.

7. The transfer robot of claim 1, wherein the photographing unit is fixedly installed on the base.

8. The transfer robot of claim 2, further comprising:
a controller,
the photographing unit acquires an image by photographing an area of each of the plurality of hands in which the substrate is placed, and
the controller determines whether the substrate is seated on each of the plurality of hands and whether the substrate is seated in a correct position from the image acquired by the photographing unit.

9. The transfer robot of claim 8, wherein the controller combines the images acquired by each of the pair of photographing units to acquire coordinates of the substrate placed on each of the plurality of hands, and determines whether the substrate is seated in the correct position by using the acquired coordinates of the substrate

10. The transfer robot of claim 8, wherein the controller extracts image data in which a focusing area is set to be limited to an edge area of the substrate from the image acquired by the photographing unit and determines whether the substrate is seated and whether the substrate is seated in the correct position.

11. The transfer robot of claim 1, wherein at least one of the plurality of arms includes a plurality of hands, and
the plurality of hands is provided to be coupled to the one arm so as to be spaced apart from each other in a vertical direction.

12. An apparatus for processing a substrate, the apparatus comprising:
an index module including a load port for loading and unloading a substrate;
a processing module including a process chamber for processing a substrate;
a controller; and
a transfer robot for transferring the substrate between the index module and the processing module,
wherein the transfer robot includes:
a base;
a plurality of arms installed above the base to be vertically spaced apart and to extend and retract in a forward and backward direction relative to the base, each having a hand supporting the substrate; and
a pair of photographing units disposed above the base,
each of the plurality of arms includes one or more hands,
the photographing units photographs an area of each of a plurality of hands in which a substrate is placed at a time, and
the area that the photographing unit photographs includes an edge area of the substrate placed on the hand.

13. The apparatus of claim 12, wherein the edge areas of the substrate photographed by the pair of photographing units are configured to be symmetrical based on a center line passing through a center of the substrate placed on the hand and parallel to the forward and backward direction of the hand when viewed from above.

14. The apparatus of claim 12, wherein optical paths of the pair of photographing units are configured to be perpendicular to each other when viewed from above.

15. The apparatus of claim 12, wherein the photographing unit includes:
a camera;
a mirror for changing the optical path of the camera; and
a polarization filter.

16. The apparatus of claim 12, wherein the photographing unit is fixedly installed on the base.

17. The apparatus of claim 12, further comprising:
a controller,
wherein the photographing unit acquires an image by photographing an area of each of the plurality of hands in which the substrate is placed, and
the controller determines whether the substrate is seated on each of the plurality of hands and whether the substrate is seated in a correct position from the image acquired by the photographing unit.

18. A transfer robot for transferring a substrate, the transfer robot comprising:
a base;
a plurality of arms installed above the base to be vertically spaced apart and to extend and retract in a forward and backward direction relative to the base, each having a hand supporting the substrate; and
a pair of photographing units fixedly installed on the base and photographing an area of each of the plurality of hands in which the substrate is placed, and
the pair of photographing units is arranged to photograph different areas of the substrate placed on the hand, respectively,
each photographing unit includes:
a camera;
a mirror for changing an optical path of the camera; and
a polarization filter,
optical paths of the pair of photographing units are configured to be perpendicular to each other when viewed from above,
the pair of photographing units is arranged to photograph different areas of the substrate placed on the hand, respectively, and
an area photographed by the photographing unit includes an edge area of the substrate.

19. The transfer robot of claim 18, further comprising:
a controller,
wherein the photographing unit acquires an image by photographing an area of each of the plurality of hands in which the substrate is placed, and
the controller determines whether the substrate is seated on each of the plurality of hands and whether the substrate is seated in a correct position from the image acquired by the photographing unit.

20. The transfer robot of claim 19, wherein the controller extracts image data in which a focusing area is set to be limited to an edge area of the substrate from the image acquired by the photographing unit and determines whether the substrate is seated and whether the substrate is seated in the correct position.
